(19) United States
(12) Patent Application Publication
(10) Pub. No.: US 2018/0252607 A1
(43) Pub. Date: Sep. 6, 2018

(54) PRESSURE SENSOR, PRESSURE SENSOR MODULE, ELECTRONIC APPARATUS, AND VEHICLE

(71) Applicant: SEIKO EPSON CORPORATION, Tokyo (JP)

(72) Inventors: Shinichi YOTSUYA, Chino-shi (JP); Junichi TAKEUCHI, Chino-shi (JP); Nobuyuki TANAKA, Chino-shi (JP); Takuya KINUGAWA, Suwa-shi (JP); Yusuke MATSUZAWA, Chino-shi (JP)

(73) Assignee: SEIKO EPSON CORPORATION, Tokyo (JP)

(21) Appl. No.: 15/897,278

(22) Filed: Feb. 15, 2018

(30) Foreign Application Priority Data
Mar. 2, 2017 (JP) 2017-039061

(51) Int. Cl. G01L 9/00; G01L 19/06; B81C 1/00; B81B 7/00

(52) U.S. Cl. CPC G01L 9/0054; G01L 9/0042; G01L 9/0055; G01L 19/0654; B81C 1/00182; B81C 2203/019; B81B 7/0038; B81B 2201/0264; B81B 2201/0292; B81B 2203/0127; B81C 1/00666

(57) ABSTRACT

A pressure sensor includes a substrate which has a diaphragm that is flexurally deformed by receiving a pressure, a side wall section which is placed on one surface side of the substrate and surrounds the diaphragm in a plan view, and a sealing layer which is placed so as to face the diaphragm through a space surrounded by the side wall section and seals the space, wherein the sealing layer includes a first silicon layer, a second silicon layer which is located on the opposite side to the substrate with respect to the first silicon layer, and a silicon oxide layer which is located between the first silicon layer and the second silicon layer, and the silicon oxide layer is sealed from the outside by being covered with the second silicon layer.

### BACKGROUND

### 1. Technical Field

The present invention relates to a pressure sensor, a production method for a pressure sensor, a pressure sensor module, an electronic apparatus, and a vehicle.

### 2. Related Art

There has been known a configuration described in JP-A-2016-102737 (Patent Document 1) as a pressure sensor. The pressure sensor described in Patent Document 1 includes a substrate having a diaphragm and a surrounding structure placed on the substrate, and a pressure reference chamber is formed therebetween. Further, the surrounding structure includes a frame-shaped wall section surrounding the pressure reference chamber and a ceiling section covering an opening of the wall section. Further, the ceiling section includes a coating layer having a through-hole for release etching, and a sealing layer which is stacked on the coating layer and seals the through-hole.

In the pressure sensor having such a configuration, the substrate is constituted by an SOI substrate, and the sealing layer is constituted by a metal material such as Al or Ti. Therefore, due to the difference in the thermal expansion coefficient between these materials, the internal stress of the diaphragm greatly changes depending on the environmental temperature. Due to this, even if the same pressure is received, a hysteresis in which the measured value varies depending on the environmental temperature occurs, and the pressure detection accuracy may be deteriorated.

In order to solve the above problem, the inventors of this application contemplated forming the sealing layer into a stacked structure of a first silicon layer, a silicon oxide layer, and a second silicon layer. However, in such a structure, when the silicon oxide layer is exposed to the outer periphery of the sealing layer, the silicon oxide layer absorbs water, and the internal stress of the sealing layer changes accompanying this. Further, the amount of water adsorbed by the silicon oxide layer varies depending on the environmental humidity, and therefore, the internal stress of the sealing layer changes depending on the environmental humidity.

In this manner, when the internal stress of the sealing layer changes depending on the environmental humidity, the internal stress of the diaphragm also changes accompanying this. Due to this, even if the same pressure is received, a hysteresis in which the measured value varies depending on the environmental humidity occurs, and the pressure detection accuracy may be deteriorated.

### SUMMARY

An advantage of some aspects of the invention is to provide a pressure sensor capable of reducing the effect of the environmental humidity thereon and exhibiting excellent pressure detection accuracy, a production method for the pressure sensor, a pressure sensor module, an electronic apparatus, and a vehicle.

The advantage can be achieved by the following configurations.

A pressure sensor according to an aspect of the invention includes a substrate which has a diaphragm that is flexurally deformed by receiving a pressure, a side wall section which is placed on one surface side of the substrate and surrounds the diaphragm in a plan view, and a sealing layer which is placed so as to face the diaphragm through a space surrounded by the side wall section and seals the space, wherein the sealing layer includes a first silicon layer, a second silicon layer which is located on the opposite side to the substrate with respect to the first silicon layer, and a silicon oxide layer which is located between the first silicon layer and the second silicon layer, and the silicon oxide layer is sealed from the outside by being covered with the second silicon layer.

According to this configuration, adsorption of water by the silicon oxide layer can be suppressed. Therefore, the effect of the environmental humidity thereon is reduced, and thus, a pressure sensor which can exhibit excellent pressure detection accuracy is obtained.

In the pressure sensor according to the aspect of the invention, it is preferred that in the silicon oxide layer, the main surface on the first silicon layer side is covered with the first silicon layer, the main surface on the second silicon layer side is covered with the second silicon layer, and the side surfaces are covered with the second silicon layer.

According to this configuration, the silicon oxide layer can be sealed with the first silicon layer and the second silicon layer by a simple configuration.

In the pressure sensor according to the aspect of the invention, it is preferred that the outer edge of the silicon oxide layer is located inside the outer edge of the first silicon layer in a plan view of the sealing layer, and the second silicon layer is stacked on the silicon oxide layer and on a region exposed from the silicon oxide layer of the first silicon layer.

According to this configuration, the silicon oxide layer can be sealed with the first silicon layer and the second silicon layer by a simple configuration.

In the pressure sensor according to the aspect of the invention, it is preferred that the substrate contains silicon.

According to this configuration, handling in production is facilitated, and excellent processing dimensional accuracy can be exhibited. Further, the difference in the thermal expansion coefficient between the substrate and the sealing layer is decreased, and the change in the amount of flexure of the diaphragm depending on the environmental temperature can be reduced. Therefore, the deviation of the detected pressure value attributed to the environmental temperature (temperature hysteresis) can be reduced. As a result, a pressure sensor having excellent pressure detection accuracy is formed.

A production method for a pressure sensor according to an aspect of the invention includes preparing a substrate which has a diaphragm forming region, forming a side wall section which surrounds the diaphragm forming region in a plan view of the substrate and a sealing layer which is placed so as to face the diaphragm forming region through a space surrounded by the side wall section and seals the space on one surface side of the substrate, and forming a diaphragm which is flexurally deformed by receiving a pressure in the diaphragm forming region, wherein in the forming the sealing layer, a first silicon layer, a second silicon layer which is located on the opposite side to the space with respect to the first silicon layer, and a silicon oxide layer which is located between the first silicon layer and the second silicon layer are formed, and the silicon oxide layer is sealed from the outside by being covered with the second silicon layer.

According to this configuration, adsorption of water by the silicon oxide layer can be suppressed. Therefore, the effect of the environmental humidity thereon is reduced, and thus, a pressure sensor which can exhibit excellent pressure detection accuracy is obtained.

In the production method for a pressure sensor according to the aspect of the invention, it is preferred that the forming the sealing layer includes forming the first silicon layer, forming the silicon oxide layer on the first silicon layer so that the first silicon layer is exposed from the periphery thereof in a plan view of the first silicon layer, and forming the second silicon layer on the silicon oxide layer and a region exposed from the silicon oxide layer of the first silicon layer.

According to this configuration, the sealing layer can be formed by a simple step.

A pressure sensor module according to an aspect of the invention includes the pressure sensor according to the aspect of the invention and a package which houses the pressure sensor.

According to this configuration, the effect of the pressure sensor according to the aspect of the invention can be received, and therefore, a pressure sensor module having high reliability is obtained.

An electronic apparatus according to an aspect of the invention includes the pressure sensor according to the aspect of the invention.

According to this configuration, the effect of the pressure sensor according to the aspect of the invention can be received, and therefore, an electronic apparatus having high reliability is obtained.

A vehicle according to an aspect of the invention includes the pressure sensor according to the aspect of the invention.

According to this configuration, the effect of the pressure sensor according to the aspect of the invention can be received, and therefore, a vehicle having high reliability is obtained.

### BRIEF DESCRIPTION OF THE DRAWINGS

The invention will be described with reference to the accompanying drawings, wherein like numbers reference like elements.

FIG. 1 is a cross-sectional view showing a pressure sensor according to a first embodiment of the invention.

FIG. 2 is a plan view showing a pressure sensor section included in the pressure sensor shown in FIG. 1.

FIG. 3 is a view showing a bridge circuit including the pressure sensor section shown in FIG. 2.

FIG. 4 is an enlarged cross-sectional view of a sealing layer included in the pressure sensor shown in FIG. 1.

FIG. 5 is a cross-sectional view showing a variation of the pressure sensor shown in FIG. 1.

FIG. 6 is a cross-sectional view showing a variation of the pressure sensor shown in FIG. 1.

FIG. 7 is a graph showing a change in stress in a silicon oxide film due to adsorption of water.

FIG. 8 is a flowchart showing a production step of the pressure sensor shown in FIG. 1.

FIG. 9 is a cross-sectional view for illustrating a production method for the pressure sensor shown in FIG. 1.

FIG. 10 is a cross-sectional view for illustrating the production method for the pressure sensor shown in FIG. 1.

FIG. 11 is a cross-sectional view for illustrating the production method for the pressure sensor shown in FIG. 1.

FIG. 12 is a cross-sectional view for illustrating the production method for the pressure sensor shown in FIG. 1.

FIG. 13 is a cross-sectional view for illustrating the production method for the pressure sensor shown in FIG. 1.

FIG. 14 is a cross-sectional view for illustrating the production method for the pressure sensor shown in FIG. 1.

FIG. 15 is a cross-sectional view for illustrating the production method for the pressure sensor shown in FIG. 1.

FIG. 16 is a cross-sectional view for illustrating the production method for the pressure sensor shown in FIG. 1.

FIG. 17 is a cross-sectional view for illustrating the production method for the pressure sensor shown in FIG. 1.

FIG. 18 is a cross-sectional view of a pressure sensor module according to a second embodiment of the invention.

FIG. 19 is a plan view of a support substrate included in the pressure sensor module shown in FIG. 18.

FIG. 20 is a perspective view showing an altimeter as an electronic apparatus according to a third embodiment of the invention.

FIG. 21 is a front view showing a navigation system as an electronic apparatus according to a fourth embodiment of the invention.

FIG. 22 is a perspective view showing a car as a vehicle according to a fifth embodiment of the invention.

### DESCRIPTION OF EXEMPLARY EMBODIMENTS

Hereinafter, a pressure sensor, a production method for a pressure sensor, a pressure sensor module, an electronic apparatus, and a vehicle according to the invention will be described in detail based on embodiments shown in the accompanying drawings.

### First Embodiment

First, a pressure sensor according to a first embodiment of the invention will be described.

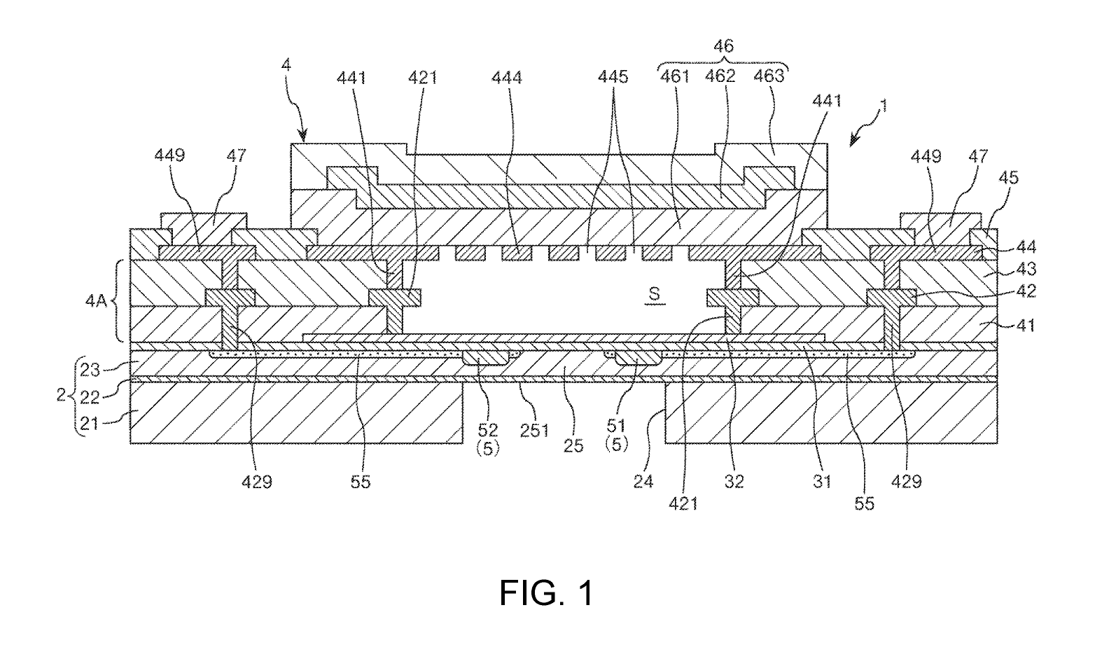

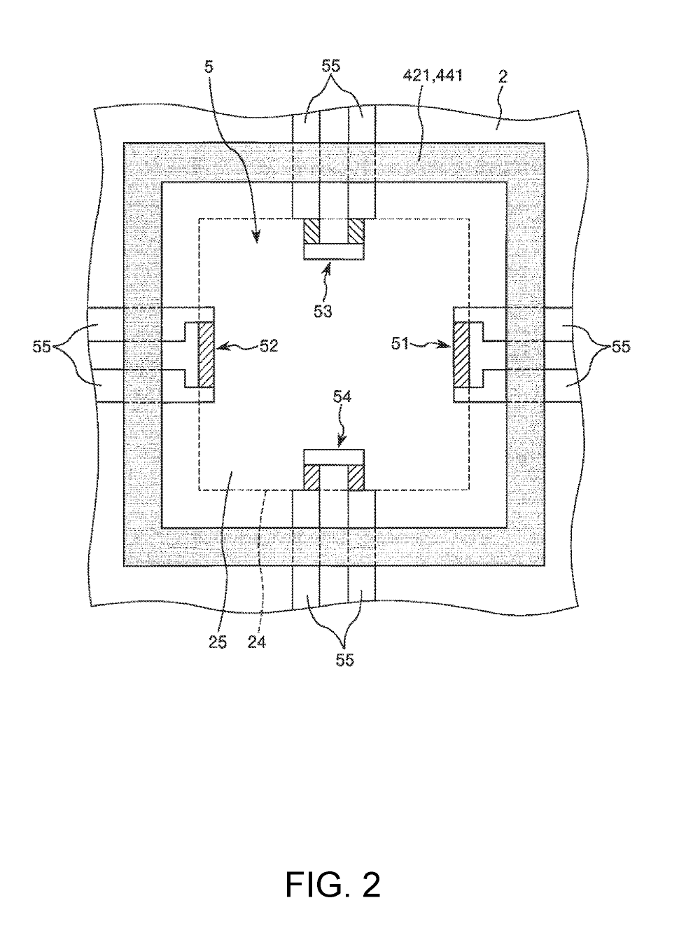

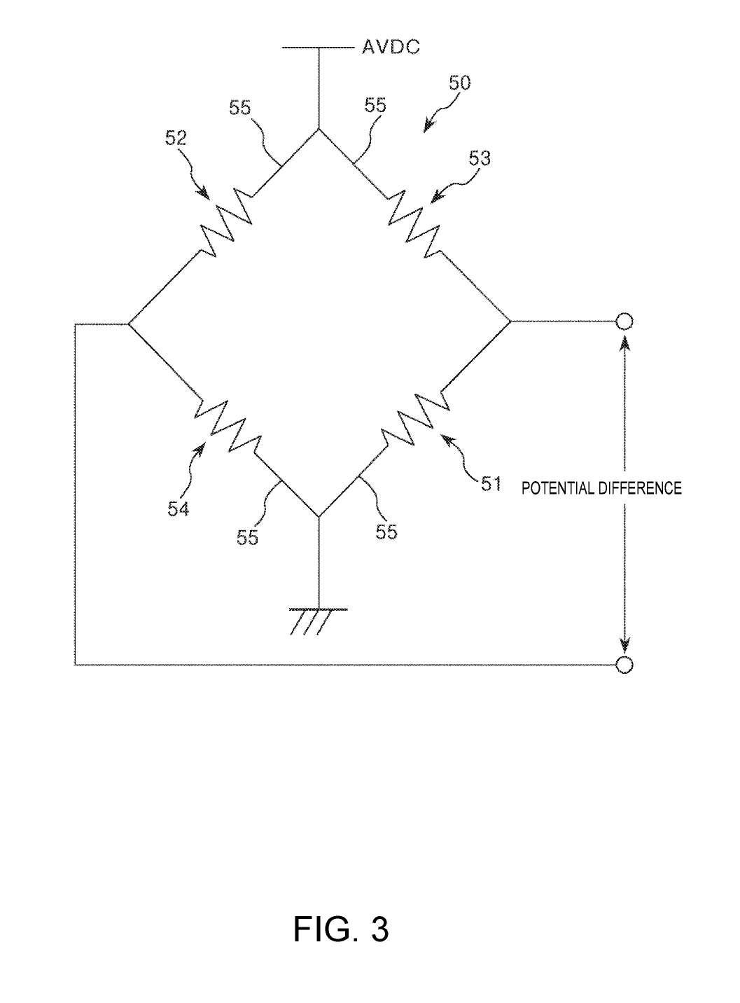

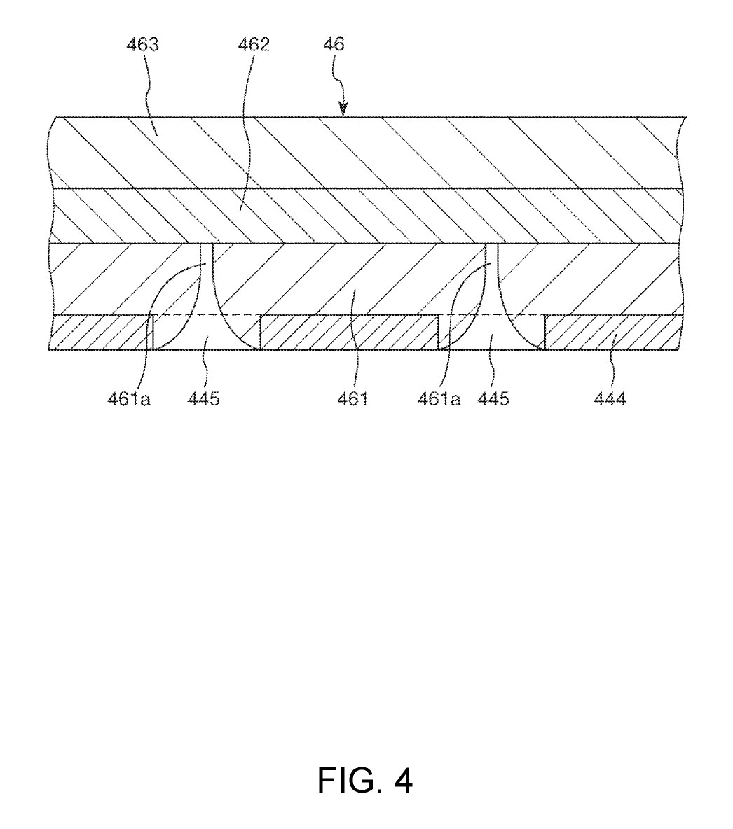

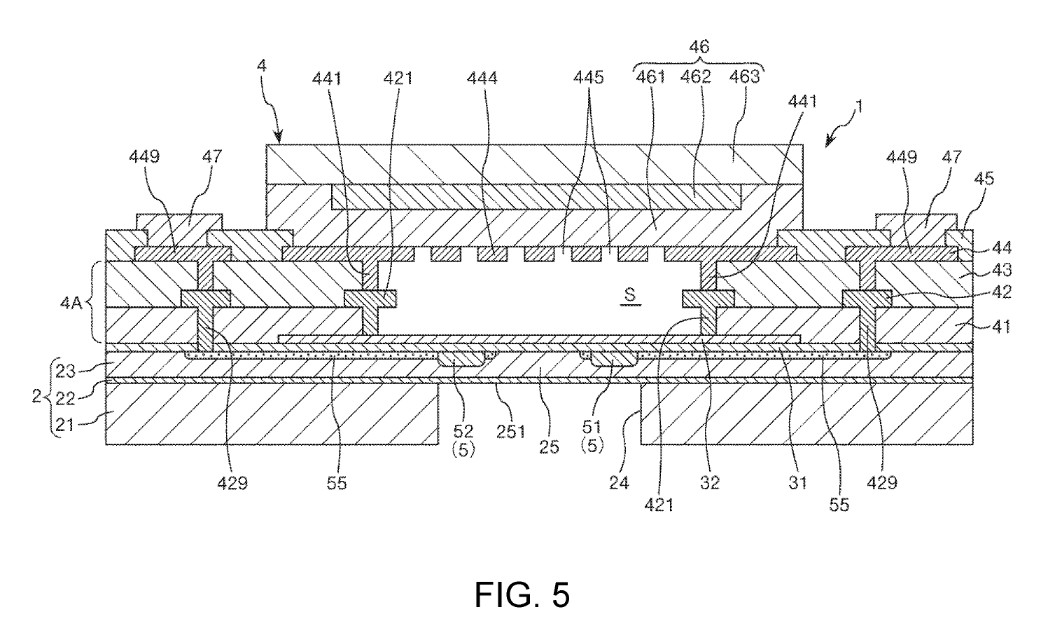

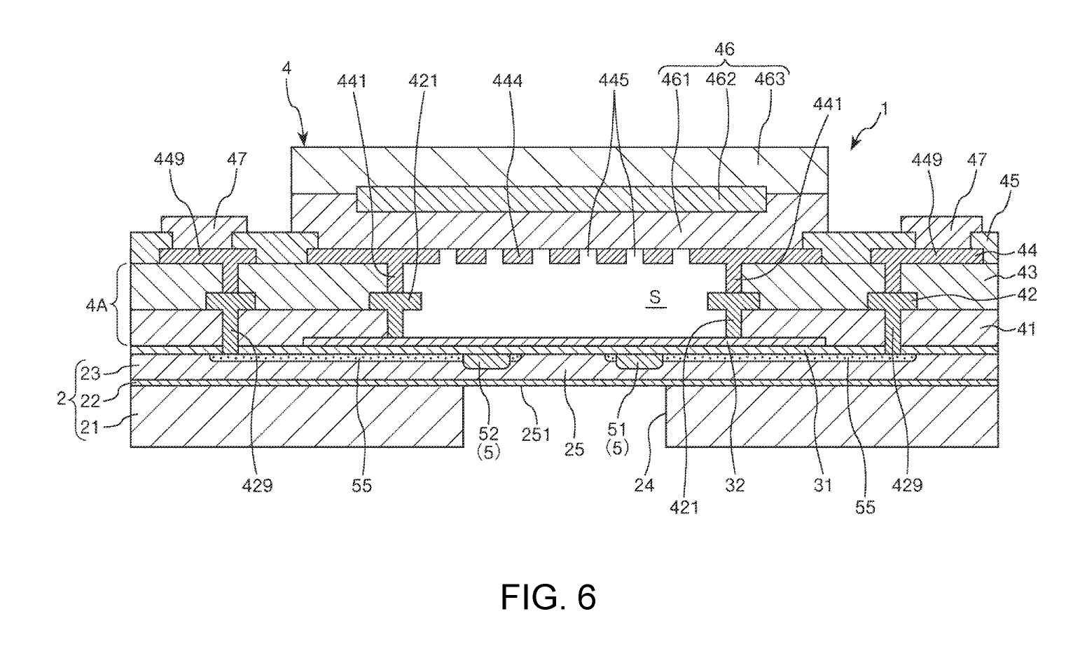

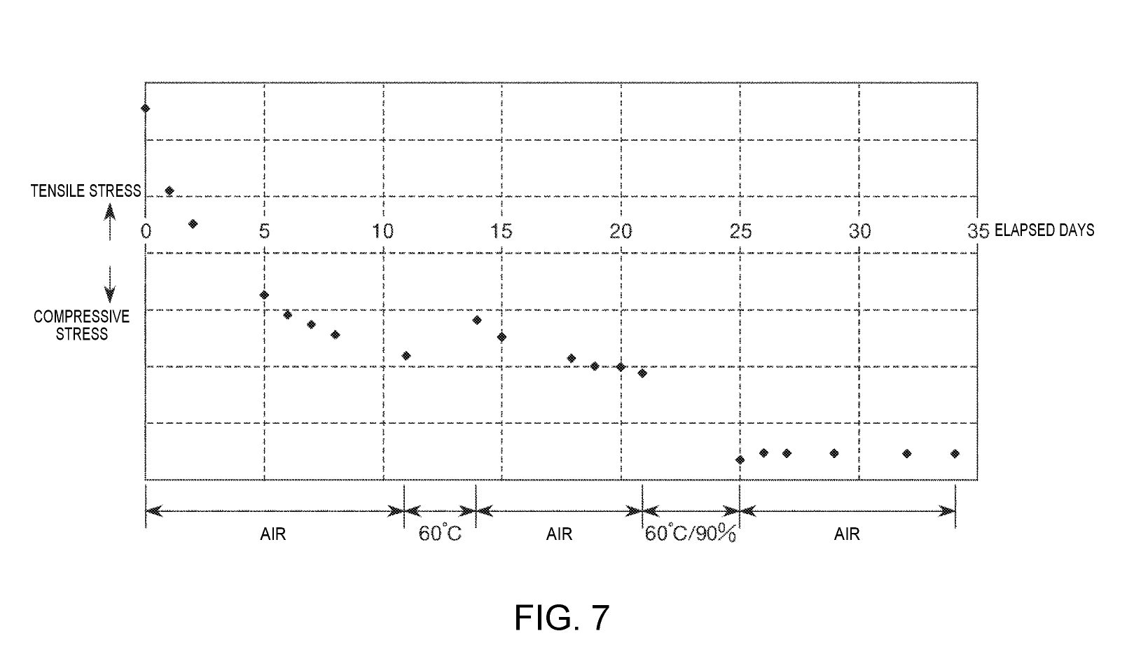

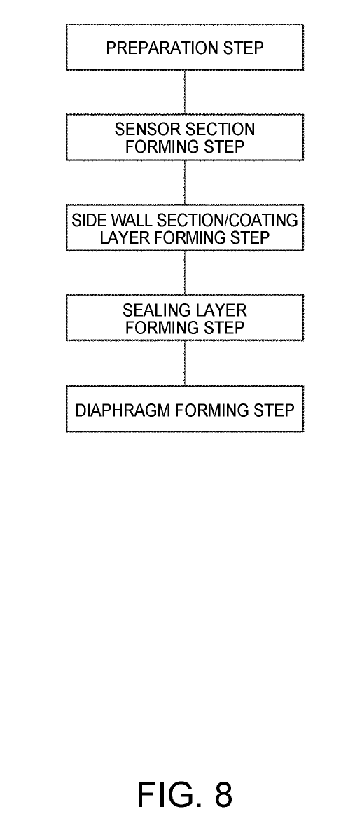

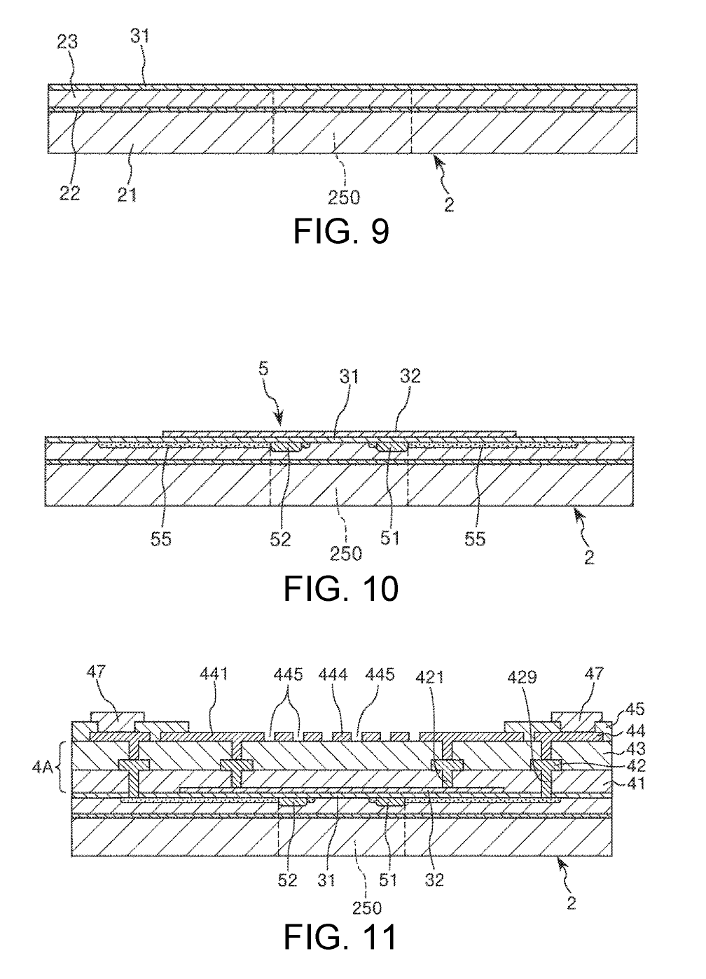

FIG. 1 is a cross-sectional view showing the pressure sensor according to the first embodiment of the invention. FIG. 2 is a plan view showing a pressure sensor section included in the pressure sensor shown in FIG. 1. FIG. 3 is a view showing a bridge circuit including the pressure sensor section shown in FIG. 2. FIG. 4 is an enlarged cross-sectional view of a sealing layer included in the pressure sensor shown in FIG. 1. FIGS. 5 and 6 are each a cross-sectional view showing a variation of the pressure sensor shown in FIG. 1. FIG. 7 is a graph showing a change in stress in a silicon oxide film due to adsorption of water. FIG. 8 is a flowchart showing a production step of the pressure sensor shown in FIG. 1. FIGS. 9 to 17 are each a cross-sectional view for illustrating a production method for the pressure sensor shown in FIG. 1. In the following description, in each of FIGS. 1, 4, 5, 6, and 9 to 17, the upper side and the lower side are also referred to as “upper” and “lower”, respectively. Further, a plan view of a substrate, that is, a plan view viewed from the vertical direction in FIG. 1 is also simply referred to as “a plan view”.

As shown in FIG. 1, a pressure sensor 1 includes a substrate 2 which has a diaphragm 25 that is flexurally deformed by receiving a pressure, a pressure reference chamber S (cavity section) which is placed on the upper surface side of the diaphragm 25, a surrounding structure 4 which forms the pressure reference chamber S along with the substrate 2, and a sensor section 5 which is placed on the upper surface side of the diaphragm 25.

The substrate 2 is constituted by an SOI substrate including a first layer 21 which is constituted by silicon, a third layer 23 which is placed on the upper side of the first layer 21 and is constituted by silicon, and a second layer 22 which is placed between the first layer 21 and the third layer 23 and is constituted by silicon oxide. That is, the substrate 2 contains silicon (Si). According to this, handling in production is facilitated, and excellent processing dimensional accuracy can be exhibited. However, the substrate 2 is not limited to the SOI substrate, and for example, a single-layer silicon substrate can also be used. The substrate 2 may be a substrate (semiconductor substrate) constituted by a semiconductor material other than silicon, for example, germanium, gallium arsenide, gallium arsenide phosphide, gallium nitride, silicon carbide, or the like.

Further, in the substrate 2, a diaphragm 25 which is thinner than the peripheral portion and is flexurally deformed by receiving a pressure is provided. In the substrate 2, a bottomed recessed section 24 which opens downward is formed, and a portion on the upper side of this recessed section 24 (a portion where the substrate 2 is thinned due to the recessed section 24) becomes the diaphragm 25. Further, the lower surface of the diaphragm 25 becomes a pressure receiving surface 251 which receives a pressure. In this embodiment, the plan view shape of the diaphragm 25 is an approximate square, however, the plan view shape of the diaphragm 25 is not particularly limited, and may be, for example, a circle.

Here, in this embodiment, the recessed section 24 is formed by dry etching using a silicon deep etching device. Specifically, the recessed section 24 is formed by repeating the step of isotropic etching, protective film formation, and anisotropic etching from the lower surface side of the substrate 2 so as to dig the first layer 21. When etching reaches the second layer 22 by repeating this step, the second layer 22 serves as an etching stopper and the etching is terminated, whereby the recessed section 24 is obtained. According to such a forming method, the inner wall side surface of the recessed section 24 is substantially perpendicular to the main surface of the substrate 2, and therefore, the opening area of the recessed section 24 can be made small. Therefore, a decrease in the mechanical strength of the substrate 2 can be suppressed, and also an increase in the size of the pressure sensor 1 can be suppressed.

However, the forming method for the recessed section 24 is not limited to the above-mentioned method, and the recessed section 24 may be formed by, for example, wet etching. Further, in this embodiment, the second layer 22 remains on the lower surface side of the diaphragm 25, however, this second layer 22 may be removed. That is, the diaphragm 25 may be constituted by a single layer of the third layer 23. According to this, the diaphragm 25 can be made thinner, and thus, the diaphragm 25 which is more easily flexurally deformed is obtained.

The thickness of the diaphragm 25 is not particularly limited and varies also depending on the size or the like of the diaphragm 25, however, for example, in a case where the width of the diaphragm 25 is 100 μm or more and 150 μm or less, the thickness thereof is preferably 1 μm or more and 10 μm or less, more preferably 1 μm or more and 3 μm or less. By setting the thickness within such a range, the diaphragm 25 which is sufficiently thin and is more easily flexurally deformed by receiving a pressure while sufficiently maintaining the mechanical strength is obtained.

In the diaphragm 25, the sensor section 5 capable of detecting a pressure to act on the diaphragm 25 is provided. As shown in FIG. 2, the sensor section 5 includes four piezoresistive elements 51, 52, 53, and 54 provided in the diaphragm 25. The piezoresistive elements 51, 52, 53, and 54 are electrically connected to one another through a wiring 55 and constitute abridge circuit 50 (Wheatstone bridge circuit) shown in FIG. 3. To the bridge circuit 50, a drive circuit which supplies (applies) a drive voltage AVDC is connected. Then, the bridge circuit 50 outputs a detection signal (voltage) in accordance with the change in the resistance value of the piezoresistive element 51, 52, 53, or 54 based on the flexure of the diaphragm 25. Due to this, a pressure received by the diaphragm 25 can be detected based on this output detection signal.

In particular, the piezoresistive elements 51, 52, 53, and 54 are placed in an outer edge portion of the diaphragm 25. When the diaphragm 25 is flexurally deformed by receiving a pressure, a large stress is applied particularly to the outer edge portion in the diaphragm 25, and therefore, by placing the piezoresistive elements 51, 52, 53, and 54 in the outer edge portion, the above-mentioned detection signal can be increased, and thus, the pressure detection sensitivity is improved. The placement of the piezoresistive elements 51, 52, 53, and 54 is not particularly limited, and for example, the piezoresistive elements 51, 52, 53, and 54 may be placed across the outer edge of the diaphragm 25.

Each of the piezoresistive elements 51, 52, 53, and 54 is formed by, for example, doping (diffusing or injecting) an impurity such as phosphorus or boron into the third layer 23 of the substrate 2. The wiring 55 is formed by, for example, doping (diffusing or injecting) an impurity such as phosphorus or boron into the third layer 23 of the substrate 2 at a higher concentration than in the piezoresistive elements 51, 52, 53, and 54.

The configuration of the sensor section 5 is not particularly limited as long as it can detect a pressure received by the diaphragm 25. For example, a configuration in which at least one piezoresistive element which does not constitute the bridge circuit 50 is placed in the diaphragm 25 may be adopted. Further, as the sensor section, an electrostatic capacitance type which detects a pressure based on a change in electrostatic capacitance may be used other than the piezoresistive type as in this embodiment.

Further, as shown in FIG. 1, on the upper surface of the substrate 2, a first insulating film 31 composed of a silicon oxide film (SiO₂ film) and a second insulating film 32 composed of a silicon nitride film (SiN film) are formed. By the first insulating film 31, the interface states of the piezoresistive elements 51, 52, 53, and 54 are reduced, and the occurrence of noise can be suppressed. Further, by the second insulating film 32, the sensor section 5 can be protected from water, gases, etc. At least one of the first and second insulating films 31 and 32 may be omitted or may be constituted by a different material.

Further, as shown in FIG. 1, on the upper side of the diaphragm 25, the pressure reference chamber S is provided. This pressure reference chamber S is formed by being surrounded by the substrate 2 and the surrounding structure 4. The pressure reference chamber S is a hermetically sealed space, and the pressure in the pressure reference chamber S becomes the reference value of a pressure to be detected by the pressure sensor 1. In particular, the pressure reference chamber S is preferably in a vacuum state (for example, about 10 Pa or less). According to this, the pressure sensor 1 can be used as an “absolute pressure sensor” which detects a pressure with reference to vacuum, and the pressure sensor 1 with high convenience is formed. However, the pressure reference chamber S may not be in a vacuum state as long as the pressure therein is kept constant.

The surrounding structure 4 forms the pressure reference chamber S between the surrounding structure 4 and the substrate 2. Such a surrounding structure 4 includes an interlayer insulating film 41 placed on the substrate 2, a wiring layer 42 placed on the interlayer insulating film 41, an interlayer insulating film 43 placed on the wiring layer 42 and the interlayer insulating film 41, a wiring layer 44 placed on the interlayer insulating film 43, a surface protective film 45 placed on the wiring layer 44 and the interlayer insulating film 43, a sealing layer 46 placed on the wiring layer 44 and the surface protective film 45, and a terminal 47 placed on the surface protective film 45.

The interlayer insulating films 41 and 43 each have a frame shape and are placed so as to surround the diaphragm 25 in a plan view. By these interlayer insulating films 41 and 43, a side wall section 4A is constituted. Further, in the inside of the side wall section 4A, a space, that is, the pressure reference chamber S is formed.

The wiring layer 42 includes a frame-shaped guard ring 421 placed so as to surround the pressure reference chamber S and a wiring section 429 connected to the wiring 55 of the sensor section 5. The wiring layer 44 includes a frame-shaped guard ring 441 placed so as to surround the pressure reference chamber S and a wiring section 449 connected to the wiring 55.

The wiring layer 44 is located on the ceiling of the pressure reference chamber S (an upper end face of the space formed inside the side wall section 4A) and includes a coating layer 444 (lid section) formed integrally with the guard ring 441. In this coating layer 444, a plurality of through-holes 445 for making the inside and the outside of the pressure reference chamber S communicate with each other are formed. The plurality of through-holes 445 are holes for release etching when removing a sacrificial layer which fills the pressure reference chamber S until the middle of the production. Further, the guard rings 421 and 441 each function as an etching stopper when performing the above-mentioned release etching.

On the coating layer 444, the sealing layer 46 is placed, and by this sealing layer 46, the through-holes 445 are sealed, and the airtight pressure reference chamber S is formed. The surface protective film 45 has a function of protecting the surrounding structure 4 from water, gases, dust, scratches, etc. The surface protective film 45 is placed on the interlayer insulating film 43 and the wiring layer 44 so as not to close the through-holes 445 of the coating layer 444. Further, on the surface protective film 45, a plurality of terminals 47 electrically connected to the sensor section 5 through the wiring sections 429 and 449 are provided.

In such a surrounding structure 4, as the interlayer insulating films 41 and 43, for example, an insulating film such as a silicon oxide film (SiO₂ film) can be used. Further, as the wiring layers 42 and 44 and the terminal 47, for example, a metal film such as an aluminum film can be used. Further, as the surface protective film 45, for example, a silicon oxide film, a silicon nitride film, a polyimide film, an epoxy resin film, or the like can be used.

Next, the sealing layer 46 will be described in detail. As shown in FIG. 1, the sealing layer 46 has a three-layer structure including a first silicon layer 461 placed on the coating layer 444, a second silicon layer 463 placed on the upper side of the first silicon layer 461, and a silicon oxide layer 462 placed between the first silicon layer 461 and the second silicon layer 463. By forming the sealing layer 46 into a stacked structure in this manner, the through-holes 445 can be more reliably sealed.

To be more specific, as shown in FIG. 4, depending on the film forming method, a through-hole 461a communicating with the through-hole 445 is formed in the first silicon layer 461, and there is a fear that the through-hole 445 cannot be sealed only with the first silicon layer 461. The diameter of the through-hole 461a can be made small by forming the first silicon layer 461 thick, however, when the diameter is reduced to some extent, it becomes difficult to make the diameter smaller than that, and therefore, no matter how thick the first silicon layer 461 is made, the through-hole 461a is not completely closed in some cases. Therefore, the silicon oxide layer 462 is placed on the first silicon layer 461, and the through-hole 445 is closed with this silicon oxide layer 462.

However, when the silicon oxide layer 462 is exposed to the outside, the silicon oxide layer 462 adsorbs water, and the internal stress of the sealing layer 46 changes depending on the environmental humidity. Therefore, by placing the second silicon layer 463 on the silicon oxide layer 462 to cover the silicon oxide layer 462 with the second silicon layer 463, the silicon oxide layer 462 is airtightly sealed from the outside. According to this, the silicon oxide layer 462 can be protected from water, and therefore, the change in the internal stress of the sealing layer 46 depending on the environmental humidity can be suppressed. The sealing layer 46 is not limited to the configuration in which the through-hole 461a is formed in the first silicon layer 461 as described above, and may not have the through-hole 461a , or the through-hole 461a may be closed in the middle of the first silicon layer 461.

The first silicon layer 461 is configured to contain silicon (Si), and is particularly constituted by silicon in this embodiment. Further, the silicon oxide layer 462 is configured to contain silicon oxide (SiO₂), and is particularly constituted by silicon oxide in this embodiment. Further, the second silicon layer 463 is configured to contain silicon (Si), and is particularly constituted by silicon in this embodiment. In this manner, by configuring each of the layers 461, 462, and 463 to contain silicon (Si), as also described in the below-mentioned production method, the sealing layer 46 can be easily formed by a semiconductor process.

The first silicon layer 461 and the second silicon layer 463 may each contain a material other than silicon (for example, a material inevitably mixed therein in the production). Similarly, the silicon oxide layer 462 may contain a material other than silicon oxide (for example, a material inevitably mixed therein in the production).

In the sealing layer 46, the silicon oxide layer 462 is used as a layer placed on the first silicon layer 461. Due to this, a large etching selection ratio between the first silicon layer 461 and the silicon oxide layer 462 can be ensured. According to this, as also described in the below-mentioned production method for the pressure sensor 1, it is possible to easily perform patterning of the silicon oxide layer 462 using an etching technique on the first silicon layer 461.

Further, in the sealing layer 46, the second silicon layer 463 constituted by the same material as the first silicon layer 461 is used as a layer placed on the silicon oxide layer 462. Due to this, as also described in the below-mentioned production method for the pressure sensor 1, it is possible to perform patterning of the first silicon layer 461 and the second silicon layer 463 simultaneously (in the same step) using an etching technique. As a result, the production step of the pressure sensor 1 can be reduced, and thus, it becomes easy to produce the pressure sensor 1.

The thickness of the first silicon layer 461 is not particularly limited, but is preferably, for example, 0.1 μm or more and 10 μm ar less. According to this, the first silicon layer 461 does not become excessively thick, and also the occurrence of a pinhole in the first silicon layer 461 can be suppressed. Due to this, the through-hole 445 of the coating layer 444 can be more reliably sealed (or the diameter of the through-hole 461a can be made sufficiently small, and the through-hole 445 can be more reliably sealed with the silicon oxide layer 462 placed thereon).

The thickness of the silicon oxide layer 462 is not particularly limited, but is preferably, for example, 0.5 μm or more and 2.0 μm or less. According to this, the through-hole 445 can be more reliably sealed along with the first silicon layer 461, and also an excessive increase in the thickness of the silicon oxide layer 462 can be prevented.

The thickness of the second silicon layer 463 is not particularly limited, but is preferably, for example, 0.1 μm or more and 10 μm or less. According to this, the occurrence of a pinhole in the second silicon layer 463 can be suppressed, and the silicon oxide layer 462 can be more reliably sealed between the second silicon layer 463 and the first silicon layer 461. Due to this, the silicon oxide layer 462 can be more effectively protected from water. Further, an excessive increase in the thickness of the second silicon layer 463 can be prevented.

According to the sealing layer 46 having such a configuration, a silicon material is contained in each of the substrate 2 and the sealing layer 46 facing each other across the pressure reference chamber S. Due to this, the difference in the thermal expansion coefficient between the substrate 2 and the sealing layer 46 is decreased, and the change in the amount of flexure of the diaphragm 25 depending on the environmental temperature can be reduced. Therefore, the deviation of the measured value attributed to the environmental temperature can be reduced, and as a result, the pressure sensor 1 having excellent pressure detection accuracy is formed.

Further, as shown in FIG. 1, the surface, which can be exposed to the outside, of the silicon oxide layer 462 is covered with the second silicon layer 463, and therefore, the silicon oxide layer 462 is airtightly sealed from the outside. That is, the entire region of the surface, which can be exposed to the outside, of the silicon oxide layer 462 is covered with the second silicon layer 463 and does not exposed on the surface of the sealing layer 46. Further, the entire region of the silicon oxide layer 462 is covered with the first silicon layer 461 and the second silicon layer 463, and is not exposed on the surface of the sealing layer 46 (excluding a portion exposed on the pressure reference chamber S from the through-hole 461a ). According to this, the silicon oxide layer 462 can be protected from water (moisture) in the outside, and adsorption of water by the silicon oxide layer 462 can be suppressed. Further, penetration of water from the interface between the first silicon layer 461 and the silicon oxide layer 462 or the interface between the second silicon layer 463 and the silicon oxide layer 462 can also be suppressed. Therefore, the change in the internal stress of the sealing layer 46 depending on the environmental humidity and the change in the internal stress of the diaphragm 25 accompanying this can be suppressed. Accordingly, the deviation of the measured value attributed to the environmental temperature can be reduced, and the pressure sensor 1 having excellent pressure detection accuracy is formed.

Further, the lower surface (the main surface on the first silicon layer 461 side) of the silicon oxide layer 462 is covered with the first silicon layer 461, the upper surface (the main surface on the second silicon layer 463 side) thereof is covered with the second silicon layer 463, and the side surfaces thereof are covered with the second silicon layer 463. According to this, the silicon oxide layer 462 can be sealed with the first silicon layer 461 and the second silicon layer 463 by a simple configuration. The configuration of the sealing layer 46 is not limited thereto, and for example, the side surfaces of the silicon oxide layer 462 may be covered with the first silicon layer 461 as shown in FIG. 5, or may be covered with the first silicon layer 461 and the second silicon layer 463 as shown in FIG. 6.

Further, the outer edge of the silicon oxide layer 462 is located inside the outer edge of the first silicon layer 461 in a plan view of the sealing layer 46, and the second silicon layer 463 is stacked on the silicon oxide layer 462 and on a region (outer edge portion) exposed from the silicon oxide layer 462 of the first silicon layer 461. According to this, the silicon oxide layer 462 can be sealed with the first silicon layer 461 and the second silicon layer 463 by a simple configuration.

The configuration is not limited thereto, and for example, the outer edge of the silicon oxide layer 462 may be located outside the outer edge of the first silicon layer 461 in a plan view of the sealing layer 46. In this case, the lower surface of the silicon oxide layer 462 may sometimes be exposed from the first silicon layer 461, however, by covering the silicon oxide layer 462 with the second silicon layer 463 from the upper side thereof, the exposure of the silicon oxide layer 462 to the outside can be prevented.

Hereinabove, the pressure sensor 1 has been described. As described above, such a pressure sensor 1 includes the substrate 2 having the diaphragm 25 which is flexurally deformed by receiving a pressure, the side wall section 4A which is placed on the upper surface (one surface) side of the substrate 2 and surrounds the diaphragm 25 in a plan view, and the sealing layer 46 which is placed so as to face the diaphragm 25 through the pressure reference chamber S (space) surrounded by the side wall section 4A and seals the pressure reference chamber S. Further, the sealing layer 46 includes the first silicon layer 461, the second silicon layer 463 which is located on the opposite side to the substrate 2 with respect to the first silicon layer 461 (on the upper side), and the silicon oxide layer 462 which is located between the first silicon layer 461 and the second silicon layer 463. The silicon oxide layer 462 is sealed from the outside by being covered with the second silicon layer 463. According to this, the silicon oxide layer 462 can be protected from water (moisture), and adsorption of water by the silicon oxide layer 462 can be suppressed. Further, penetration of water from the interface between the first silicon layer 461 and the silicon oxide layer 462 or the interface between the second silicon layer 463 and the silicon oxide layer 462 can also be suppressed. Therefore, the change in the internal stress of the sealing layer 46 depending on the environmental humidity and the change in the internal stress of the diaphragm 25 accompanying this can be suppressed. Due to this, the effect of the environmental humidity thereon is reduced, and the pressure sensor 1 which can exhibit excellent pressure detection accuracy is formed.

FIG. 7 is a graph showing a change in the stress in a silicon oxide film due to adsorption of water. The graph shown in FIG. 7 is obtained by calculating the film stress in a silicon oxide film formed on a silicon wafer using the Stoney formula and plotting the calculated values. Here, it is sufficient to describe the trend of the change in the stress in the silicon oxide film, and therefore, a detailed description of the experiment such as the Stoney formula is omitted.

First, after forming a silicon oxide film, the silicon oxide film was left in the air for 11 days. As a result, the silicon oxide film gradually adsorbed water, and the film stress in the silicon oxide film gradually changed from tensile stress to compressive stress. Subsequently, the silicon oxide film was left in an environment of 60° C. for 72 hours, and thereafter left in the air from day 14 to day 21. The film stress on day 14 changed toward the initial value with respect to the film stress on day 11, however, this is due to a decrease in water in the silicon oxide film by leaving the silicon oxide film under a high temperature of 60° C. However, by leaving the silicon oxide film in the air again, the silicon oxide film adsorbed water, and therefore, the film stress in the silicon oxide film changed to the compressive stress side from day 14 to day 21. Subsequently, the silicon oxide film was left in an environment of 60° C. and 90% RH for 72 hours, and thereafter left in the air from day 25 to day 34. The film stress on day 25 changed to the compressive stress side with respect to the film stress on day 21, however, this is due to an increase in water in the silicon oxide film by leaving the silicon oxide film under a high humidity of 90% RH. As described above, it is found that in the silicon oxide film, the internal stress is likely to change according to the environmental humidity.

The configuration of the pressure sensor 1 is not limited to the above-mentioned configuration. For example, in this embodiment, the sealing layer 46 has a configuration in which the following three layers: the first silicon layer 461, the silicon oxide layer 462, and the second silicon layer 463 are stacked, but may further include another layer. Specifically, for example, at least one or more other layers may be interposed at least one of between the coating layer 444 and the first silicon layer 461, between the first silicon layer 461 and the silicon oxide layer 462, between the silicon oxide layer 462 and the second silicon layer 463, and on the upper surface of the second silicon layer 463.

Next, a production method for the pressure sensor 1 will be described. As shown in FIG. 8, the production method for the pressure sensor 1 includes a preparation step of preparing the substrate 2 having a diaphragm forming region 250, a sensor section forming step of forming the sensor section 5 on the substrate 2, a side wall section/coating layer forming step of forming the side wall section 4A and the coating layer 444 (lid section) on the substrate 2, a sealing layer forming step of forming the sealing layer 46 on the coating layer 444, and a diaphragm forming step of forming the diaphragm 25 which is flexurally deformed by receiving a pressure in the diaphragm forming region 250 of the substrate 2.

### Preparation Step

First, as shown in FIG. 9, the substrate 2 composed of an SOI substrate in which the first layer 21, the second layer 22, and the third layer 23 are stacked is prepared. In this stage, the diaphragm 25 is not formed in the diaphragm forming region 250 of the substrate 2. Subsequently, for example, by thermally oxidizing the surface of the third layer 23, the first insulating film 31 composed of a silicon oxide film is formed on the upper surface of the substrate 2.

### Sensor Section Forming Step

Subsequently, as shown in FIG. 10, the sensor section 5 is formed on the upper surface of the substrate 2 by injecting an impurity such as phosphorus or boron thereinto. Subsequently, the second insulating film 32 is formed on the upper surface of the first insulating film 31 by a sputtering method, a CVD method, or the like.

### Side Wall Section/Coating Layer Forming Step

Subsequently, as shown in FIG. 11, on the substrate 2, the interlayer insulating film 41, the wiring layer 42, the interlayer insulating film 43, the wiring layer 44, the surface protective film 45, and the terminal 47 are sequentially formed in predetermined patterns using a sputtering method, a CVD method, or the like. By doing this, the frame-shaped side wall section 4A which surrounds the diaphragm forming region 250 in a plan view of the substrate and the coating layer 444 (lid section) which covers the side wall section 4A and has the through-holes 445 for making the inside and the outside of the side wall section 4A communicate with each other are obtained. In this embodiment, the interlayer insulating films 41 and 43 are constituted by silicon oxide, and the wiring layers 42 and 44 are constituted by aluminum.

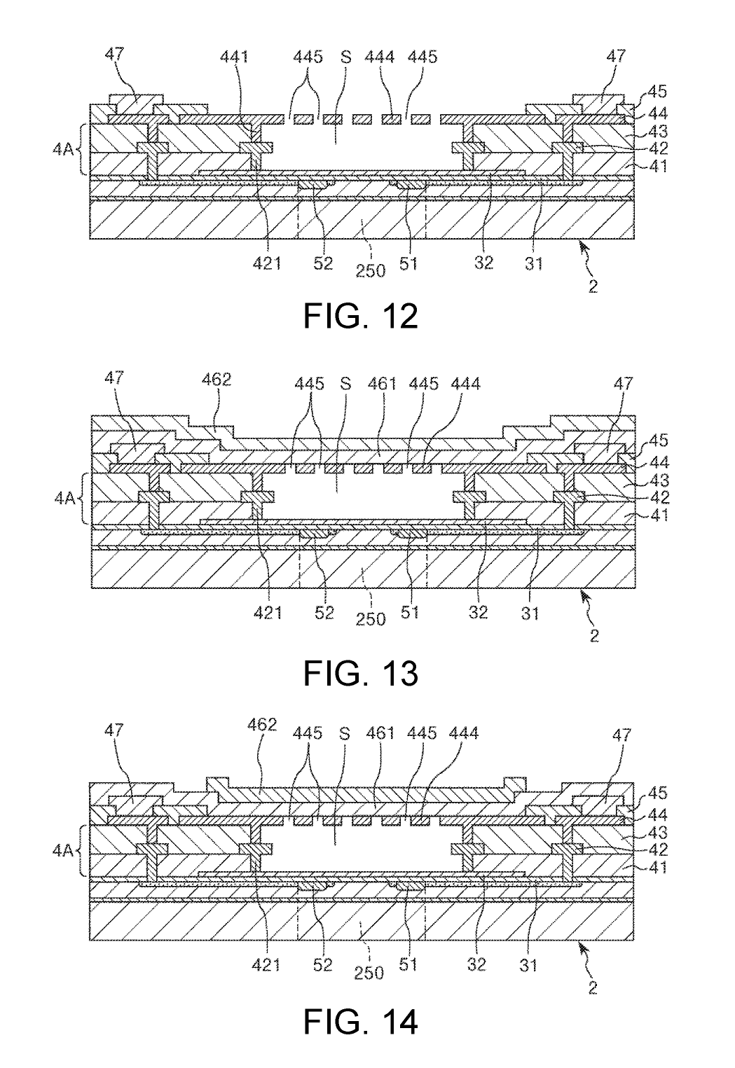

Subsequently, the substrate 2 is, for example, exposed to an etching solution such as buffered hydrofluoric acid. By doing this, as shown in FIG. 12, the interlayer insulating films 41 and 43 located inside the guard rings 421 and 441 are removed through the through-holes 445 of the coating layer 444, whereby the pressure reference chamber S is formed. At this time, the guard rings 421 and 441 each function as an etching stopper.

### Sealing Layer Forming Step

Subsequently, as shown in FIG. 13, on the upper surface of the coating layer 444 and the surface protective film 45, the first silicon layer 461 and the silicon oxide layer 462 are formed sequentially each using a sputtering method, a CVD method, or the like. Subsequently, as shown in FIG. 14, the silicon oxide layer 462 is patterned using a photolithographic technique and an etching technique. In this state, the first silicon layer 461 is exposed from the periphery of the silicon oxide layer 462. In other words, the outer edge of the silicon oxide layer 462 is located inside the outer edge of the first silicon layer 461. As the patterning method for the silicon oxide layer 462, by utilizing wet etching using an etching solution such as buffered hydrofluoric acid, a large etching selection ratio between the silicon oxide layer 462 and the first silicon layer 461 can be ensured. Therefore, only the silicon oxide layer 462 can be patterned while more reliably leaving the first silicon layer 461.

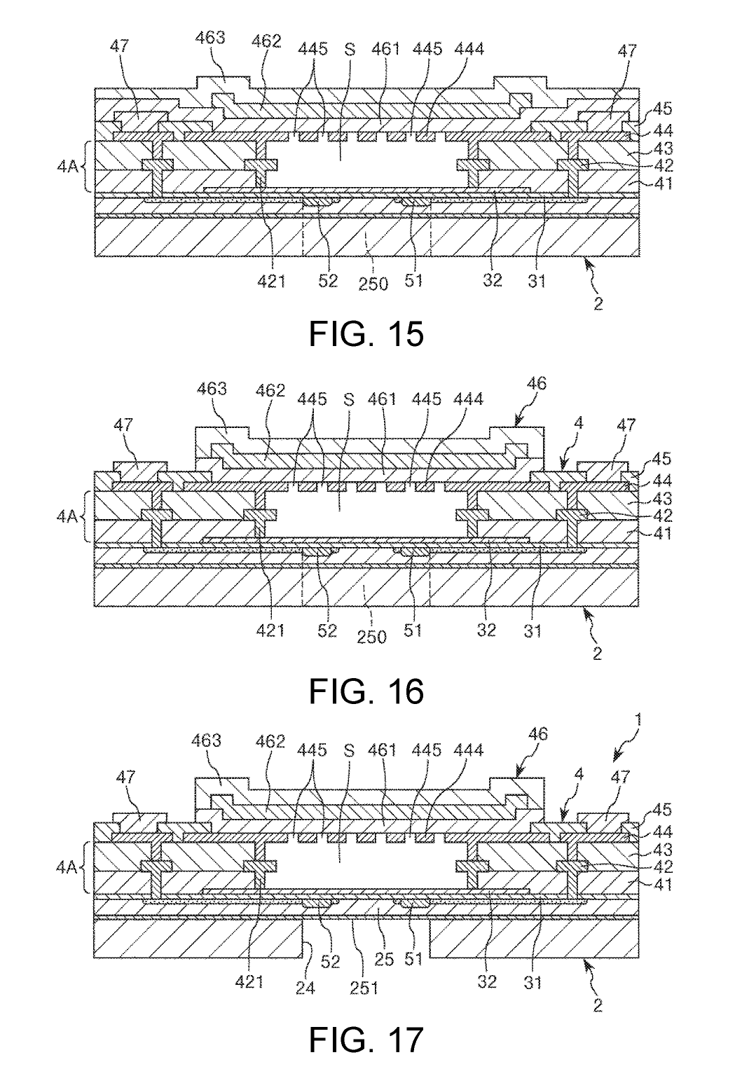

Subsequently, as shown in FIG. 15, on the upper surfaces of the silicon oxide layer 462 and the first silicon layer 461, the second silicon layer 463 is formed using a sputtering method, a CVD method, or the like. By doing this, the silicon oxide layer 462 is in a state where the upper surface and the side surfaces thereof are covered with the second silicon layer 463. As a result, the silicon oxide layer 462 is airtightly sealed from the outside by the second silicon layer 463.

Subsequently, as shown in FIG. 16, the first silicon layer 461 and the second silicon layer 463 are simultaneously patterned using a photolithographic technique and an etching technique. By doing this, the sealing layer 46 is obtained. By forming the first silicon layer 461 and the second silicon layer 463 from the same material, these layers can be simultaneously patterned as described above. Therefore, the production step of the pressure sensor 1 can be reduced, and thus, it becomes easier to produce the pressure sensor 1.

### Diaphragm Forming Step

Subsequently, as shown in FIG. 17, by etching the first layer 21 using, for example, a dry etching (particularly, silicon deep etching) method, the recessed section 24 which opens to the lower surface is formed in the diaphragm forming region 250, whereby the diaphragm 25 is obtained. As described above, the pressure sensor 1 is obtained. The order of the diaphragm forming step is not particularly limited, and for example, the diaphragm forming step may be performed prior to the sensor section forming step, or may be performed between the sensor section forming step and the sealing layer forming step.

Hereinabove, the production method for the pressure sensor 1 has been described. As described above, the production method for the pressure sensor 1 includes a step of preparing the substrate 2 having the diaphragm forming region 250, a step of forming the side wall section 4A which surrounds the diaphragm forming region 250 in a plan view of the substrate 2, and the sealing layer 46 which is placed so as to face the diaphragm forming region 250 through the pressure reference chamber S (space) surrounded by the side wall section 4A and seals the pressure reference chamber S on the upper surface (one surface) side of the substrate 2, and a step of forming the diaphragm 25 which is flexurally deformed by receiving a pressure in the diaphragm forming region 250. Then, in the step of forming the sealing layer 46, the first silicon layer 461, the second silicon layer 463 which is located on the opposite side to the pressure reference chamber S with respect to the first silicon layer 461 (on the upper side), and the silicon oxide layer 462 which is located between the first silicon layer 461 and the second silicon layer 463 so as to seal the silicon oxide layer 462 from the outside by being covered with the second silicon layer 463. According to this, the silicon oxide layer 462 can be protected from water (moisture), and adsorption of water by the silicon oxide layer 462 can be suppressed. Further, penetration of water from the interface between the first silicon layer 461 and the silicon oxide layer 462 or the interface between the second silicon layer 463 and the silicon oxide layer 462 can also be suppressed. Therefore, the change in the internal stress of the sealing layer 46 depending on the environmental humidity and the change in the internal stress of the diaphragm 25 accompanying this can be suppressed. Due to this, the effect of the environmental humidity thereon is reduced, and thus, the pressure sensor 1 which can exhibit excellent pressure detection accuracy is obtained.

In particular, as described above, the step of forming the sealing layer 46 includes a step of forming the first silicon layer 461, a step of forming the silicon oxide layer 462 on the first silicon layer 461 so that the first silicon layer 461 is exposed from the periphery thereof, and a step of forming the second silicon layer 463 on the silicon oxide layer 462 and on a region exposed from the silicon oxide layer 462 of the first silicon layer 461. According to such a production method, the silicon oxide layer 462 can be simply sealed with the first silicon layer 461 and the second silicon layer 463. That is, the sealing layer 46 can be formed by a simple step.

### Second Embodiment

Next, a pressure sensor module according to a second embodiment of the invention will be described.

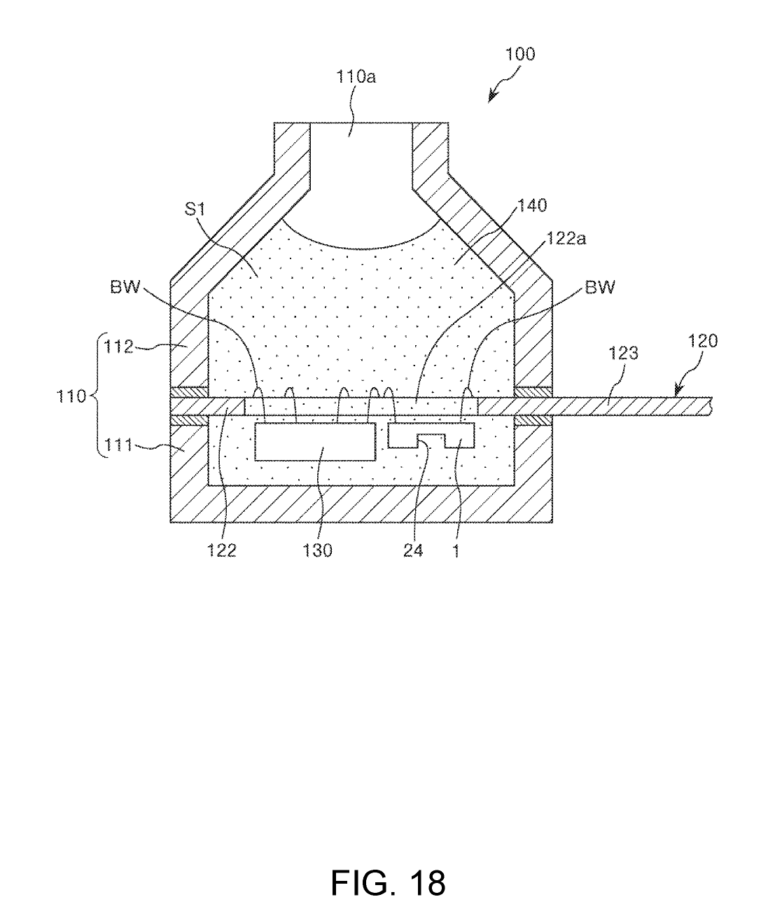

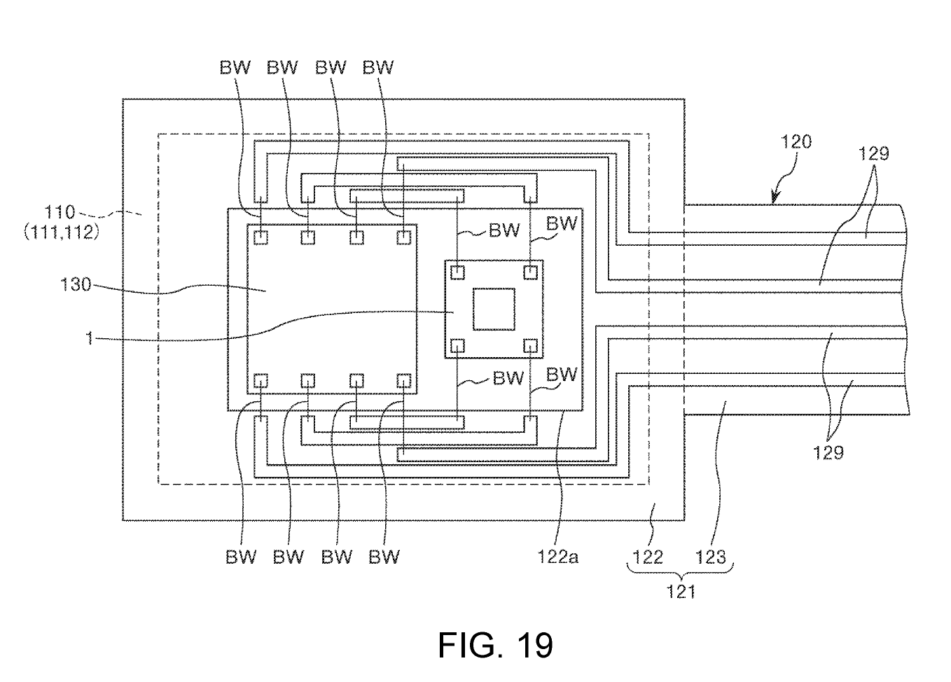

FIG. 18 is a cross-sectional view of the pressure sensor module according to the second embodiment of the invention. FIG. 19 is a plan view of a support substrate included in the pressure sensor module shown in FIG. 18.

Hereinafter, with respect to the pressure sensor module according to the second embodiment, different points from the above-mentioned embodiment will be mainly described, and the description of the same matter will be omitted.

As shown in FIG. 18, a pressure sensor module 100 includes a package 110 which has an internal space S1, a support substrate 120 which is placed so as to be drawn out from the inside of the internal space S1 to the outside of the package 110, a circuit element 130 and a pressure sensor 1, each of which is supported by the support substrate 120 in the internal space S1, and a filling section 140 which is formed by filling a filler as described later in the internal space S1. According to such a pressure sensor module 100, the pressure sensor 1 can be protected by the package 110 and the filling section 140. As the pressure sensor 1, for example, the pressure sensor according to the first embodiment described above can be used.

The package 110 includes a base 111 and a housing 112, and the base 111 and the housing 112 are bonded to each other through an adhesive layer so as to sandwich the support substrate 120 therebetween. The package 110 formed in this manner includes an opening 110a formed in the upper end portion thereof and the internal space S1 communicating with the opening 110a.

The constituent material of the base 111 and the housing 112 is not particularly limited, and examples thereof include insulating materials such as various types of ceramics including oxide ceramics such as alumina, silica, titania, and zirconia, and nitride ceramics such as silicon nitride, aluminum nitride, and titanium nitride, and various types of resin materials including polyethylene, polyamide, polyimide, polycarbonate, acrylic resins, ABS resins, and epoxy resins, and among these, it is possible to use one type or two or more types in combination. Above all, it is particularly preferred to use various types of ceramics.

Hereinabove, the package 110 has been described, however, the configuration of the package 110 is not particularly limited as long as the function can be exhibited.

The support substrate 120 is sandwiched between the base 111 and the housing 112 and placed so as to be drawn out from the inside of the internal space S1 to the outside of the package 110. Further, the support substrate 120 supports the circuit element 130 and the pressure sensor 1, and also electrically connects the circuit element 130 and the pressure sensor 1. Such a support substrate 120 includes a base material 121 having flexibility and a plurality of wirings 129 placed on the base material 121 as shown in FIG. 19.

The base material 121 includes a frame-shaped base section 122 having an opening 122a and a strip-shaped belt body 123 extending from the base section 122. The belt body 123 is sandwiched between the base 111 and the housing 112 in the outer edge portion of the base section 122 and extends to the outside of the package 110. As such a base material 121, for example, a generally used flexible printed circuit board can be used. In this embodiment, the base material 121 has flexibility, however, the entire or apart of the base material 121 may be a hard material.

The circuit element 130 and the pressure sensor 1 are located inside the opening 122a and are placed side by side in a plan view of the base material 121. Further, each of the circuit element 130 and the pressure sensor 1 is hung on the base material 121 through a bonding wire BW and is supported by the support substrate 120 in a floating state from the support substrate 120. Further, the circuit element 130 and the pressure sensor 1 are electrically connected through the bonding wires BW and the wirings 129. In this manner, by supporting the circuit element 130 and the pressure sensor 1 in a floating state with respect to the support substrate 120, a stress is less likely to be transmitted to the circuit element 130 and the pressure sensor 1 from the support substrate 120, and therefore, the pressure detection accuracy of the pressure sensor 1 is improved.

The circuit element 130 includes a drive circuit for supplying a voltage to the bridge circuit 50, a temperature compensation circuit for performing temperature compensation of an output from the bridge circuit 50, a pressure detection circuit which determines a pressure received from an output from the temperature compensation circuit, an output circuit which converts an output from the pressure detection circuit into a predetermined output form (CMOS, LV-PECL, LVDS, or the like) and outputs the converted output, and the like.

The filling section 140 is placed in the internal space S1 so as to cover the circuit element 130 and the pressure sensor 1. By such a filling section 140, the circuit element 130 and the pressure sensor 1 are protected (protected from dust and water), and also an external stress (for example, a drop impact) having acted on the pressure sensor 1 is less likely to be transmitted to the circuit element 130 and the pressure sensor 1.

Further, the filling section 140 can be constituted by a liquid or gel-like filler, and is particularly preferably constituted by a gel-like filler from the standpoint that an excessive displacement of the circuit element 130 and the pressure sensor 1 can be suppressed. According to such a filling section 140, the circuit element 130 and the pressure sensor 1 can be effectively protected from water, and also a pressure can be efficiently transmitted to the pressure sensor 1. The filler constituting such a filling section 140 is not particularly limited, and for example, a silicone oil, a fluorine-based oil, a silicone gel, or the like can be used.

Hereinabove, the pressure sensor module 100 has been described. Such a pressure sensor module 100 includes the pressure sensor 1 and the package 110 which houses the pressure sensor 1. Therefore, the pressure sensor 1 can be protected by the package 110. Further, the effect of the pressure sensor 1 described above can be received, and high reliability can be exhibited.

The configuration of the pressure sensor module 100 is not limited to the above-mentioned configuration, and for example, the filling section 140 may be omitted. Further, in this embodiment, the pressure sensor 1 and the circuit element 130 are supported in a state of being hung on the support substrate 120 by the bonding wires BW, however, for example, the pressure sensor 1 and the circuit element 130 maybe placed directly on the support substrate 120. Further, in this embodiment, the pressure sensor 1 and the circuit element 130 are placed side by side in the lateral direction, however, for example, the pressure sensor 1 and the circuit element 130 may be placed side by side in the height direction.

### Third Embodiment

Next, an electronic apparatus according to a third embodiment of the invention will be described.

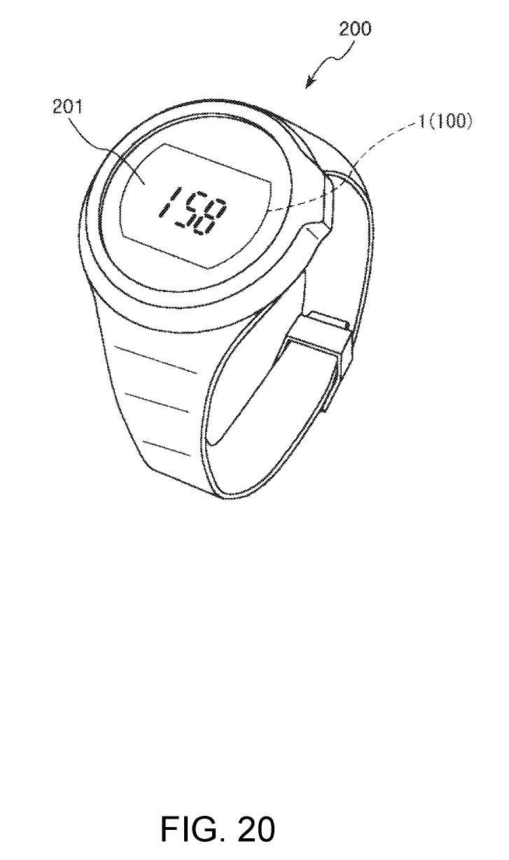

FIG. 20 is a perspective view showing an altimeter as the electronic apparatus according to the third embodiment of the invention.

As shown in FIG. 20, an altimeter 200 as the electronic apparatus can be worn on the wrist like a wristwatch. In the altimeter 200, the pressure sensor 1 (pressure sensor module 100) is mounted, and the altitude of the current location above sea level, the atmospheric pressure at the current location, or the like can be displayed on a display section 201. In this display section 201, various information such as a current time, the heart rate of a user, and weather can be displayed.

Such an altimeter 200 which is one example of the electronic apparatus includes the pressure sensor 1. Therefore, the altimeter 200 can receive the effect of the pressure sensor 1 described above and can exhibit high reliability.

### Fourth Embodiment

Next, an electronic apparatus according to a fourth embodiment of the invention will be described.

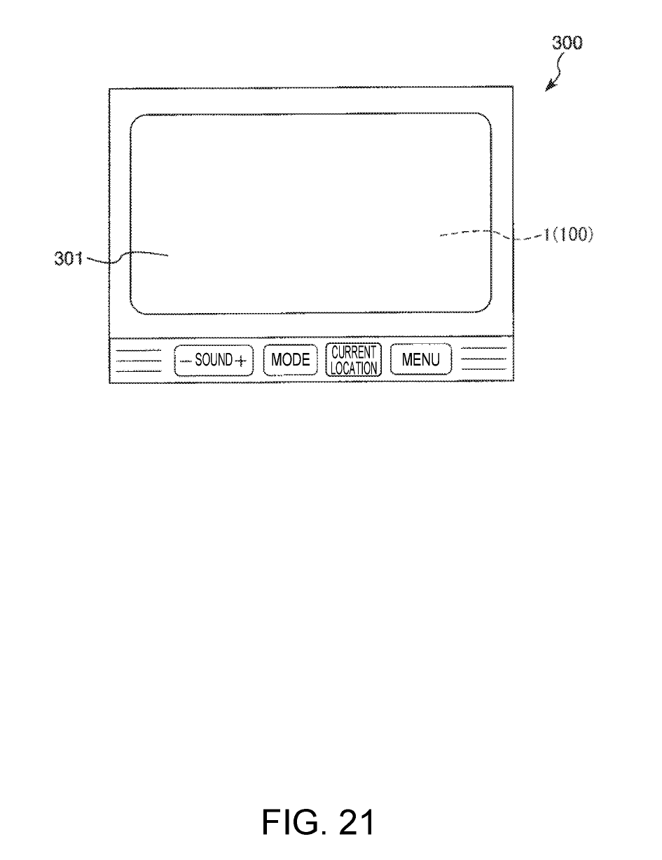

FIG. 21 is a front view showing a navigation system as the electronic apparatus according to the fourth embodiment of the invention.

As shown in FIG. 21, a navigation system 300 as the electronic apparatus includes map information (not shown), a location information acquisition unit based on a GPS (Global Positioning System), a self-contained navigation unit based on a gyroscope sensor, an accelerometer, and a vehicle speed data, the pressure sensor 1 (pressure sensor module 100), and a display section 301 which displays given location information or route information.

According to this navigation system 300, in addition to the acquired location information, altitude information can be acquired. For example, in a case where a vehicle travels on an elevated road which is at substantially the same location as a general road in terms of location information, if altitude information is not provided, a navigation system cannot determine whether the vehicle is traveling on the general road or on the elevated road, and provides the user with information of the general road as priority information. Therefore, by mounting the pressure sensor 1 on the navigation system 300 and acquiring altitude information by the pressure sensor 1, the change in altitude due to entry into the elevated road from the general road can be detected, and the user can be provided with navigation information for the state of traveling on the elevated road.

Such a navigation system 300 as one example of the electronic apparatus includes the pressure sensor 1. Therefore, the navigation system 300 can receive the effect of the pressure sensor 1 described above and can exhibit high reliability.

The electronic apparatus according to the invention is not limited to the above-mentioned altimeter and navigation system, and can be applied to, for example, a personal computer, a digital still camera, a cellular phone, a smartphone, a tablet terminal, a timepiece (including a smart watch), a drone, medical apparatuses (for example, an electronic thermometer, a sphygmomanometer, a blood glucose meter, an electrocardiographic apparatus, an ultrasonic diagnostic apparatus, and an electronic endoscope), various types of measurement apparatuses, meters and gauges (for example, meters and gauges for vehicles, aircrafts, and ships), a flight simulator, and the like.

### Fifth Embodiment

Next, a vehicle according to a fifth embodiment of the invention will be described.

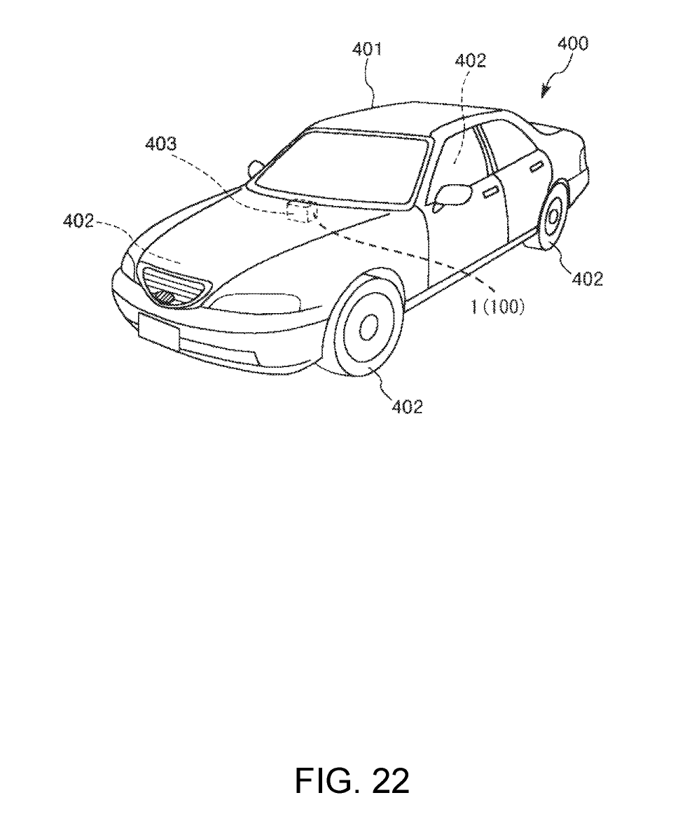

FIG. 22 is a perspective view showing a car as the vehicle according to the fifth embodiment of the invention.

As shown in FIG. 22, a car 400 as the vehicle includes a car body 401 and four wheels 402 (tires), and is configured to rotate the wheels 402 by a power source (engine) (not shown) provided in the car body 401. Further, the car 400 includes an electronic control unit (ECU) 403 mounted on the car body 401 and the pressure sensor 1 is built in this electronic control unit 403. The electronic control unit 403 ascertains the traveling state, posture, etc. of the car by detecting the acceleration, inclination, etc. of the car body 401 by the pressure sensor 1, and therefore can accurately control the wheels 402 or the like. According to this, the car 400 can safely and stably travel. The pressure sensor 1 may also be mounted on a navigation system or the like provided in the car 400.

Such a car 400 as one example of the vehicle includes the pressure sensor 1. Therefore, the car 400 can receive the effect of the pressure sensor 1 described above and can exhibit high reliability.

Hereinabove, the pressure sensor, the production method for a pressure sensor, the pressure sensor module, the electronic apparatus, and the vehicle according to the invention have been described based on the respective embodiments shown in the drawings, however, the invention is not limited thereto, and the configuration of each section can be replaced with an arbitrary configuration having the same function. Further, another arbitrary component or step may be added, and also the respective embodiments may be appropriately combined with each other.

The entire disclosure of Japanese Patent Application No. 2017-039061, filed Mar. 2, 2017 is expressly incorporated by reference herein.

What is claimed is:

1. A pressure sensor, comprising:
a substrate which has a diaphragm that is flexurally deformed by receiving a pressure;
a side wall section which is placed on one surface side of the substrate and surrounds the diaphragm in a plan view; and
a sealing layer which is placed so as to face the diaphragm through a space surrounded by the side wall section and seals the space, wherein
the sealing layer includes
a first silicon layer,
a second silicon layer which is located on the opposite side to the substrate with respect to the first silicon layer, and
a silicon oxide layer which is located between the first silicon layer and the second silicon layer, and
the silicon oxide layer is sealed from the outside by being covered with the second silicon layer.

2. The pressure sensor according to claim 1, wherein in the silicon oxide layer, the main surface on the first silicon layer side is covered with the first silicon layer, the main surface on the second silicon layer side is covered with the second silicon layer, and the side surfaces are covered with the second silicon layer.

3. The pressure sensor according to claim 2, wherein
the outer edge of the silicon oxide layer is located inside the outer edge of the first silicon layer in a plan view of the sealing layer, and
the second silicon layer is stacked on the silicon oxide layer and on a region exposed from the silicon oxide layer of the first silicon layer.

4. The pressure sensor according to claim 1, wherein the substrate contains silicon.

5. A pressure sensor module, comprising:
the pressure sensor according to claim 1; and
a package which houses the pressure sensor.

6. An electronic apparatus, comprising the pressure sensor according to claim 1.

7. A vehicle, comprising the pressure sensor according to claim 1.
